(19) United States
(12) Patent Application Publication
(10) Pub. No.: US 2004/0087128 A1
(43) Pub. Date: May 6, 2004

(54) Method and materials for printing particle-enhanced electrical contacts

(76) Inventors: Herbert J Neuhaus, Colorado Springs, CO (US); Bin Zou, Colorado Springs, CO (US)

Correspondence Address: DORSEY & WHITNEY, LLP, INTELLECTUAL PROPERTY DEPARTMENT, 370 SEVENTEENTH STREET, SUITE 4700, DENVER, CO, 80202-5647, US

(21) Appl. No.: 10/415,193

(22) PCT Filed: Oct. 24, 2001
(86) PCT No.: PCT/US01/49997

(30) Foreign Application Priority Data
Oct. 24, 2000 (US) 60243092

(51) Int. Cl. H01L 21/44

(52) U.S. Cl. 438/610

(57) ABSTRACT

The disclosed invention relates to materials and processes for creating particle-enhanced bumps on electrical contact surfaces through stencil or screen printing processes. The materials are mixtures of conductive ink, conductive paste, or conductive adhesive and conductive hard particles (104). The process involves depositing the mixture (108) onto electrical contact surfaces by stencil printing, screen printing, or other dispensing techniques (110). In another embodiment, the ink, paste, or adhesive is first stenciled or screen printed and the particles are then applied on top of the ink, paste, or adhesive deposit. Once cured (114), the deposition provides a hard, electrical contact bump on the contact surface with a rough, conductive, sandpaper-like surface that can be easily connected to an opposing contact surface without any further surface preparation of either surface.

### CROSS REFERENCE TO RELATED APPLICATIONS

This application claims the benefit of priority of U.S. provisional application Serial No. 60/243,092, filed Oct. 24, 2000, entitled “Method and Material for Printing Particle Enhanced Contacts,” which is hereby incorporated herein in its entirety by reference.

### BACKGROUND OF THE INVENTION

1. Field of the Invention

This present invention relates generally to the preparation of electrical contact surfaces for connection with opposing electrical contacts. More specifically the present invention relates to materials and methodologies for creating particle-enhanced bumps with conductive, sandpaper-like surfaces on electrical contact surfaces through stencil or screen printing, and similar depositing processes.

2. Description of Related Art

The concept of particle enhancement of contact surfaces to provide improved electrical, thermal, and mechanical connections between contact surfaces was originally disclosed by DiFrancesco in U.S. Pat. No. 5,083,697. A major advantage of the method is the exceptionally short circuit pathways created by the hard particles as they pierce through any nonconductive surface barrier, for example, oxides. Moreover, the greater surface area of the connection between contact surfaces provided by a plurality of rugged particles, compared to contact between flat surfaces alone, also provides improved thermal conductivity. (For example, 5 micron diameter industrial diamond typically has a surface area of about 1 m²/g.)

DiFrancesco suggested that particle-enhanced contact surfaces might be formed by employing a variety of techniques, such as chemical vapor deposition, sputter deposition, evaporation, electrolytic plating, and electroless plating. However, many of these methods have practical disadvantages. For example, chemical vapor deposition, sputter deposition, and evaporation require that the hard particles be particularly placed on the desired contact surfaces before the metal deposition takes place. These processes also require that the contact surfaces remain flat as not to disturb the placement of the particles.

In addition, many electrical contact materials, such as aluminum, are not compatible with such deposition and plating chemistries and techniques. In these cases special intermediary metal layers and additional process steps must be used to chemically activate the contact surface, and/or to provide a chemical separation between the contact and the metal deposition. Also, the deposition and plating processes involve the use of significant quantities of hazardous materials. These materials are corrosive and toxic and are difficult to handle and store. Safe and environmentally sound disposal of these hazardous materials is complex and costly. Finally, deposits according to these techniques accumulate, and thereby grow in thickness, at given rate. Therefore the total deposit thickness is proportional to the deposition time. Unacceptably long deposition times may be encountered if the desired application of the electrical component requires thick deposits on the contact surfaces.

A method for electrolytic co-deposition of hard particles and metal from solution in the presence of an electric current onto an electrical contact was established by Neuhaus et al. in U.S. patent application Ser. No. 09/812,140, filed Mar. 19, 2001, entitled “Electrical Component Assembly and Method of Fabrication.” Similarly, electroless co-deposition of hard particles and metal onto electrical contact surfaces was demonstrated by Bahn et al. in U.S. patent application Ser. No. 09/883,012, filed Jun. 15, 2001, entitled “Electroless Process for the Preparation of Particle-Enhanced Electric Contact Surfaces.”

Although electrolytic and electroless plating are viable technologies, they too have certain limitations that might counsel against their use in certain situations. For example, with electrolytic plating, deposition of metal and particles only occurs on surfaces electrically connected to the source of the electric current. Therefore, if multiple contacts are to be deposited upon simultaneously, either each must be electrically supplied with individual current sources or all contacts must be electrically connected to a single common current source. In practice, this severely limits the configuration and arrangement of multiple contacts that can be processed without the undesirable application and subsequent removal of temporary conductive connection layers. While an electroless plating processes does not require an electric current and is therefore are not subject to this limitation, electroless systems are much slower in building depositions than electrolytic systems.

### SUMMARY OF THE INVENTION

The present invention provides a material and method to prepare a particle-enhanced, electrically conductive surface without using the two step deposition processes or the electrolytic or electroless plating processes suggested above. The material is a mixture of conductive ink, conductive paste, or conductive adhesive, and additionally conductive hard particles, the combination of which results in a conductive solid with a conductive, sandpaper-like surface when the material dries or cures. The inventive process involves depositing the mixture onto electrical contact surfaces by stencil printing, screen printing, or other dispensing techniques. In another embodiment, the ink, paste, or adhesive is first stenciled or screen printed and the particles are then applied on top of the ink, paste, or adhesive deposit. Once cured, the deposition provides a hard, electrical contact bump on the contact surface. The physical dimensions of the screen or stencil control the deposition thickness produced by these methods. Therefore, thick deposits can be produced just as quickly as thin deposits.

With this inventive process, any configuration of contact surfaces may be processed. Since no electric current is needed, there is no need to electrically connect multiple contacts. This is particularly advantageous when the substrate is a semiconductor wafer, wherein the electrical contact surfaces (e.g., contact pads) are never electrically connected. The present invention is compatible with common contact surface materials, even those that are not compatible with electrolytic or electroless plating. In particular, aluminum contacts can be treated with no additional materials or steps. Further, in the direct dispensing processes disclosed, relatively small amounts of hazardous materials are used. All hazardous materials are evaporated during the process and no solid or liquid waste is generated.

The purpose of the deposition process of the present invention is to form an electrically conductive, sandpaper-like coating on an electrical contact surface to thereby provide enhanced electrical contact and thermal transfer between connected contact surfaces of electrical components. The conductive hard particles can pierce the surface of opposing electrical contacts, obviating the need to clean the surface of either contact. The piercing action displaces any surface impediment, for example, oxidation, oils, dirt, fluxes, or other build-up, and results in a strong electrical connection between the contacts of electrical components. The particle-enhanced surface also allows for a simple means of mechanical connection, for example, by applying non-conductive adhesives between contact surfaces. The hard particles can pierce through such adhesive as well.

### BRIEF DESCRIPTION OF THE DRAWINGS

FIG. 1 is a flow diagram of the steps involved in either stencil or particle printing contact surfaces with a mixture of a conductive liquid and hard particles according to a first embodiment of the invention.

FIG. 2 a flow diagram of the steps involved in either stencil or particle printing contact surfaces with a conductive liquid and the subsequent application of hard particles according to a second embodiment of the invention.

### DETAILED DESCRIPTION OF THE INVENTION

The present invention consists of a new bumping material and processes for depositing the bumping material onto electrical contact surfaces of electrical components. In an exemplary embodiment, electrical interconnection “bumps” with particle-enhanced surfaces are deposited on bond pads of a substrate. The electrically conductive bumps are formed by stenciling or screen printing a conductive material, such as conductive ink, conductive paste, or conductive adhesive, onto the contact surfaces. The particle enhanced surface of the bumps may be formed by either mixing conductive particles with the bumping material, such as ink, solder paste, or conductive adhesive, before stenciling or screen printing; or the conductive particles can be spread on the preformed bump surfaces after the bumps are stenciled or screened, and before the bumping materials cure.

The printing processes disclosed can be performed on almost any type of electrical component, for example, printed circuit boards, flexible circuit tape, chip carriers, chip modules, smart card contacts, smart inlay contacts, and other substrates with contact surfaces. The deposition process may applied simultaneously to a plurality of electronic components in an array. Such an array may be either one or two dimensional. Each of the plurality of electrical components has at least one electrical contact site. Once the mixture is applied to the contact sites, the electrical component array may be divided to singularize the array into many individual electrical components, thus producing many electrical components simultaneously in one operation. The method of the invention is particularly applicable to the contact pad treatment of semiconductor chips before they are diced, where the array is a semiconductor wafer.

In general, the conductive material created for use in the stenciling or screen printing processes is a mixture prepared by blending two components: (1) either a conductive ink, a conductive paste, or a conductive adhesive, and (2) conductive hard particles. Examples of the first component of the conductive material mixture include, but are not limited to: ORMET® 1007 (disclosed in U.S. Pat. No. 5,830,389)—a liquid phase transient conductive ink; Alchemetal AC-78 (Alchemetal Corporation, Jackson Heights, N.Y.)—a metal filled polymer that is conductive and solderable; and Epoxies 40-3900 (Epoxies, Etc . . . , Cranston, R.I.)—a silver filled epoxy resin. Alternatively, solder paste can also be used as conductive material. Collectively, such conductive inks, conductive pastes, or conductive adhesives may be referred to herein as viscous compounds.

The second component of the conductive material mixture is conductive hard particles, preferably either inherently conductive or non-conductive hard particles coated with metal. These conductive hard particles are in addition to and are to be distinguished from the presence any conductive particles or fillers in an ink, paste, or adhesive that produces conductivity in such materials. The addition of the conductive hard particles provides a rough, conductive, sandpaper-like surface to ink, paste, or adhesive material once cured in a solid form. This particle-enhanced, sandpaper-like surface is capable of piercing through barriers to conductivity on an opposing contact surface, obviating the need for surface preparation or cleaning before connecting the contact surfaces of two electrical components.

The conductive hard particles may be formed from a metal, for example, copper, aluminum, nickel, tin, bismuth, silver, gold, platinum, palladium, lithium, beryllium, boron, sodium, magnesium, potassium, calcium, gallium, germanium, rubidium, strontium, indium, antimony, cesium, and barium, as well as alloys and intermetallics of these metals. Nickel is a preferred metal.

As indicated, the conductive hard particles may also be formed from a nonconductive core particle covered with or surrounded by a layer of conductive metal, such as listed above. In this case, the non-conductive core particles may be non-metallic materials, for example, metal oxides, nitrides, borides, silicon and other carbides, boron fibers, carbon fibers, garnet, and diamond. Diamond is a preferred non-metallic hard particle. Nickel and copper are preferred metal coatings for such core particles. Where a thermal conductor is desired, diamond and ceramics are preferred materials. In one embodiment of the invention, hard particles are composed of a diamond core plated with a layer of nickel. The conductive hard particles may also be covered with a thin layer of gold. Gold provides low contact resistance and prevents oxidation of the contact surface. Alternatives to gold may include platinum, palladium, chrome, palladium-nickel alloy, and tin nickel alloy.

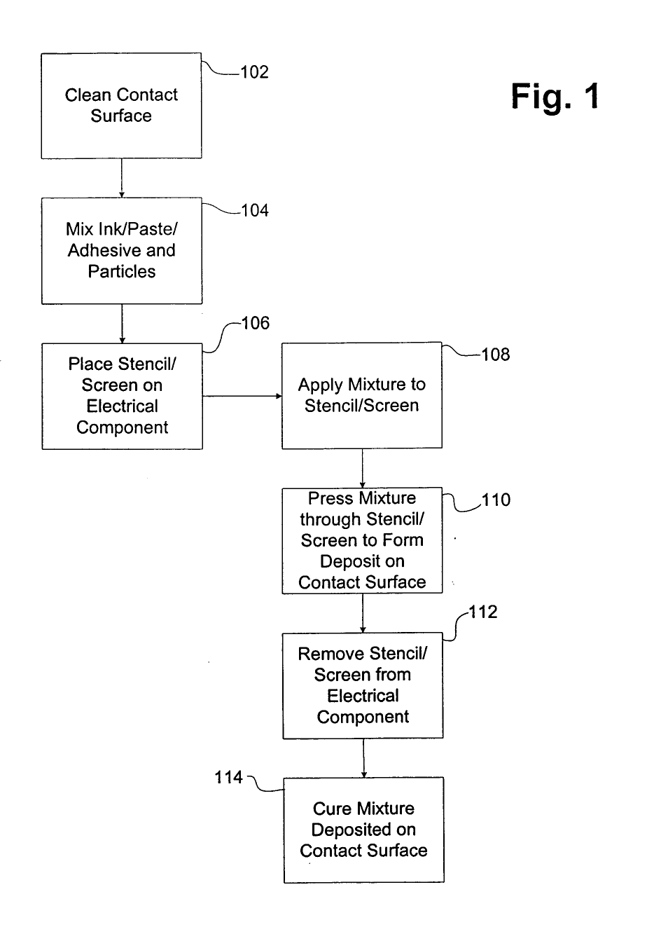

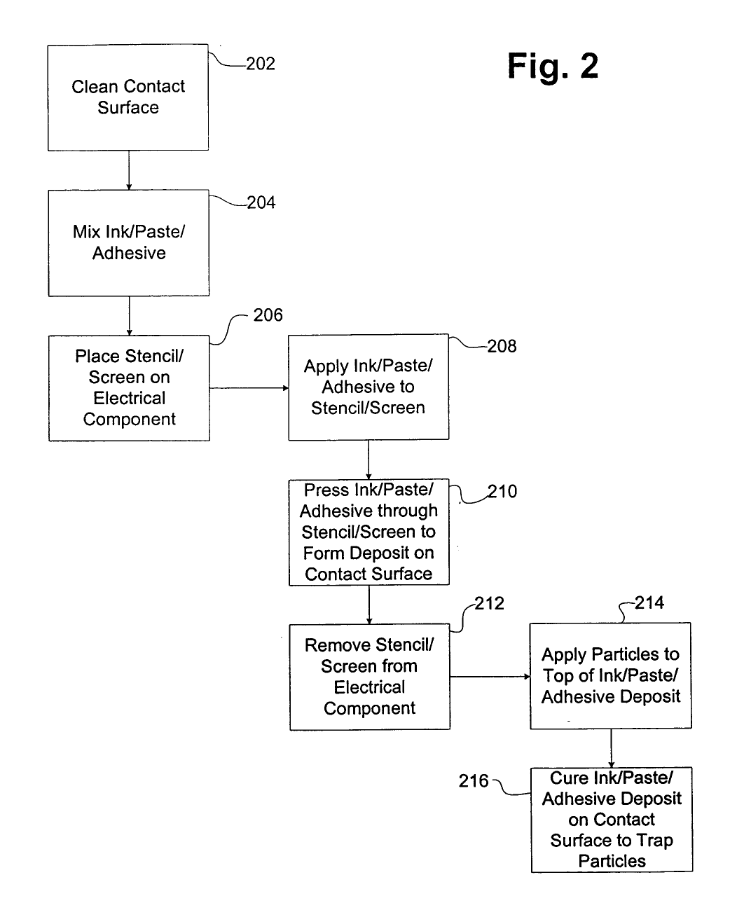

The deposition process, as depicted in FIGS. 1 and 2, in general, consists of surface preparation, mixing, materials deposition, and curing. It is well known that good adhesion starts with proper surface preparation of the contact surfaces (step 102, 202). A proper preparation is one whereby surface contamination is removed, which leaves a clean, oxide-free surface. Depending on the type of the contact surface and contaminations, different pretreatments are needed. Typically, surface contaminants that must be removed before applying the conductive ink or paste may include one or more of the following: moisture, organic contaminants (e.g., oils and lubricants), buffing compounds, oxide films, dirt, and fluxes. Usually, one may use acids, acetone, methy ethyl ketone or other comparable solvent to thoroughly clean the contact surface of the substrates. Contamination under the deposition coating will cause problems that may lead to electrical connection failures. For some substrates, additional surface preparation steps, for example, sandblasting may be necessary to ensure quality adhesion.

Depending on the type of the conductive surface desired, there are a few ways to prepare the materials. One can either mix the hard particles with the conductive ink, paste, or adhesive thoroughly before depositing as depicted in the process flow of FIG. 1, or the hard particles can be added to a preformed ink, paste, or adhesive “bump” surface after the ink, paste, or adhesive is applied and before it is cured, as depicted in FIG. 2. In the first embodiment shown in FIG. 1, the conductive particles are mixed with the ink, paste, or adhesive (step 104). There may additionally be a prior substep as the formula for a particular ink, paste, or adhesive itself may be made of two or more subcomponents. In the case of the process of FIG. 2, wherein the particles are not mixed with the ink, paste, or adhesive, this mixing step is noted at step 204. For example, the Alchemetal AC-78 paste and the Epoxies Etc. 40-3900 silver filled epoxy resin each require the premixing of various components prepare the paste or adhesive. The formula recipes for various inks, pastes, and adhesives vary significantly and one should closely follow the suggestions by the manufacturers of these materials.

In order to achieve a successful stencil or screen printed deposition, careful attention should be paid to the ink, paste, or adhesive material and the stencil or screen. The rheology of the ink, paste, or adhesive is important to a sufficient deposit to avoid creating bridges of deposition material between individual contact surfaces or causing voids within the deposition area of the stencil or screen apertures. Inks, pastes, or adhesives containing chemical components that create difficult-to-remove residues should not be used. The ink, paste, or adhesive deposition performance can generally be predicted based on detailed analysis of the ink, paste, or adhesive movement through the stencil aperture or screen. In order to achieve high quality printing, it is also important to consider the size of hard particles, and the weight ratio of the particle to the ink, paste, or adhesive, in combination with the rheological properties of the ink or paste, such as viscosity. The ink, paste, or adhesive should be adjusted to a proper viscosity. Ink, paste, or adhesive with too high viscosity may be difficult to deposit and the surface profile may be hard to control. However, ink, paste, or adhesive with too low viscosity may have too high mobility which may present a particle settlement problem, wherein the particles do not remain on the surface of the bump. The choice of the stencil or screen is also important because the stencil or screen largely determines the accuracy and the dimension of the deposition. Attention needs to be paid to these parameters during the mixing process.

Through experiments and testing of this invention, it has also been found that the electrical conductivity is a complex function of the formula of the ink, paste, or adhesive, the size of the particles, and the concentration of hard particles in the ink, paste, or adhesive. Properly choosing the conductive ink, paste, or adhesive and the conductive hard particles is critical to ensure low electrical resistivity.

The bumping material can be deposited by either stencil printing or screen-printing methods. As is well known, a stencil is generally a sheet with impervious regions and apertures for allowing the ink, paste, or adhesive and hard particles to pass through to the substrate underneath. For the purposes of this invention, stencils of as thin as 50 microns and up to 1-2 millimeters may be used. Similarly well known, screen printing generally employs a fine, mesh fabric screen covered with an emulsion. The desired pattern is imposed over the emulsion and the screen is exposed to light. The exposed areas of the emulsion hardens into an impenetrable surface, while the emulsion is rinsed away from the unexposed areas protected by the pattern, thereby allowing the ink, paste, or adhesive and hard particles to pass through to the substrate underneath.

The stencil or screen is placed upon the electrical component (step 106, 206) and then either the apertures in the stencil or the patterns in the screen are normally registered with the contact surfaces of the electrical component. In the first embodiment of FIG. 1, the ink, paste, or adhesive and particle mixture is applied to the stencil or screen (step 108) and pressed through the stencil apertures or unexposed areas of the screen to form a deposit on the contact surface (step 110). In the second embodiment of FIG. 2, only the ink, paste, or adhesive is applied to the stencil or screen (step 208) and pressed through the stencil apertures or unexposed areas of the screen to form a deposit on the contact surface (step 210). In either case, once the deposits have been formed, the stencil or screen may be removed (step 112, 212).

In the second embodiment of FIG. 2, the hard particles are then applied to the surface of the ink, paste, or adhesive deposits (step 214). The hard particles may be generally spread over the electrical component such that they stick to the ink, paste, or adhesive depositions on the contact surfaces, or the particles may be dispensed over each contact site individually. In an alternative embodiment, the particles may be applied before the stencil or screen is removed so that the particles are only applied to the areas of deposition over the contact surfaces.

The purpose of the stencil or screen is to limit the application of the mixture to the contact surfaces of the electrical component only and to control the shape of the deposit. In the case of the stencil only, the thickness of the deposit is also controlled by the thickness of the stencil. For stencil or screen printing, this deposition process can be either manually, semi-automatically, or automatically controlled by appropriate printing equipment. Some substrates have recessed contact pads and are self-patterning. These do not require a stencil or screen. In these cases, the bumping mixture is squeegeed onto the substrate and material accumulates only in the recessed contact areas. The bumping material can also be applied by brushing, dipping or dispensing directly onto the contact surfaces.

The deposition mixture of ink, paste, or adhesive and hard particles is next cured, such that the hard particles are bound in the ink, paste, or adhesive (step 114, 216). Generally, the cure consists of two or three stages including: drying or solvent removal, sintering, and polymer cure. The mixture may need to be cured in an oven. The cure schedules and temperatures are specific to the conductive ink, paste, or adhesive used. The choice of hard particles used was observed to have little effect on the curing process.

For example, the curing process for Alchemetal AC-78 is as follows. The deposited material should be carefully placed into a preheated oven to cure at approximately 100-120° C. for five minutes (to remove moisture without generating bubbles). The temperature should then be raised to approximately 220° C. for 10 minutes, and finally raised to 260° C. for 5 minutes. (This is the manufacturer's recommended ideal cure cycle.) The deposit surface should not be touched before and during the curing procedure. The electrical component should then be removed from oven and allowed to cool to room temperature. The deposited material is now conductive. The manufacturer also suggests an alternative infrared curing method to avoid potential damage to the substrate caused by exposure to an elevated curing temperatures. Infrared curing is recommended for low-temperature substrates, such as plastics. Infrared curing may also be used when the curing time needs to be significantly reduced (<5 minutes).

After curing, generally a clean-up step is often needed to clean possible surface residue on deposited surface by water or solvent before applying nonconductive adhesive to bond the deposited surface with a mating contact surface to make an electrical connection.

The process of the present invention is ideal for preparing semiconductor wafers for flip chip attach at the wafer level, before chip dicing. The described process forms the required “bumps” and particle-enhanced contacts at the same time. Because this process is compatible with aluminum, the usual “under bump metalization” processes are eliminated. As aluminum is the standard contact metalization used on semiconductor wafers, all the contacts on the wafer can be treated in a single application without the need for temporary metalization to electrically connect the contact pads.

By creating particle-enhanced bumps, the present invention allows for very simple direct chip attachment methods, for example, by nonconductive adhesive as described by Neuhaus et al. in U.S. patent application Ser. No. 09/812,140, filed Mar. 19, 2001, entitled “Electrical Component Assembly and Method of Fabrication.” The present invention also provides a simple means to thermally connect a component to a substrate. In this application, the thermal conductivity of the hard particles provides a low thermal resistance path between the component and the substrate. Electrical conductivity can be achieved at the same time.

### Experimentation and Testing

Extensive experiments have been conducted at NanoPierce Technologies, Inc. in Colorado Springs, Colo. Set forth below are descriptions of four experimental examples.

Experiment 1

Ormet® 1007 was obtained from Ormet Corporation (Carlsbad, Calif.). The material was originally kept in refrigerator. The container was warmed to room temperature. Approximately 2 gram of the ink was placed in a small Pyrex® dish. Amplex™ nickel-coated diamonds of between 10 and 25 microns in diameter were added and the mixture was stirred with a small spatula. The nickel-coated diamond particles were added to the reddish brown ink until the mixture noticeably darkened from the addition of the gray particles. The relative concentrations are estimated at 1 part particles to 10 parts ink.

Aluminum, copper, and stainless steel panels were degreased and dried. No effort was made to remove the native oxides from the panels. A stencil of approximately 100 microns thickness was applied to the panels. The mixture of ink and particles was applied to the panels as thinly as possible with the spatula through the stencil. The panels were then subjected to the cure schedule recommended by Ormet Corporation. The cycle is as follows: first, 40 minutes at 95° C. in air; second, 2 minutes at 210° C. in an inert atmosphere (for example, 3M® Fluorinert FC-70 in vapor phase mode); and finally, 60 minutes at 175° C. in air.

After curing the ink-particle deposits were inspected by an optical microscope. The deposits appeared rough and sandpaper-like. The surface profile curve of the deposits was measured by a Zeiss profilometer. The variation of the surface was noted as between 5 to 20 microns. The ink-particle material was very firmly bonded to the metal panels and could not be scraped or chipped off. The samples were also sectioned in order to observe the inner structure of the cured ink-particle deposition. It was observed that particles were uniformly and firmly positioned throughout the ink with little variation from the interior to the surface. Electrical conductivity between the surface of the deposits and the panels was verified with an ohmmeter.

Experiment 2

The first experiment was repeated using Alchemetal AC-78, a conductive, metal-filled polymer paste (Alchemetal Corporation, Jackson Heights, N.Y.) instead of the conductive ink. The particles used in the mixture with the paste were Amplex RB 50% copper-coated diamonds (i.e., 50% of the particle weight is attributed to the copper) with particle diameters between 10 and 20 microns. The particle to paste ratio was similarly estimated at about 1 to 10. The following was schedule recommended by Alchemetal Corporation for AC-78 was followed: first, 5 minutes at 100° C. in air, and second 220 for 10 minutes in air, and 5 minutes at 260° C. in air. Optical inspection, adhesion, and electrical conductivity results were identical with the results of the first experiment.

Experiment 3

The first experiment was again repeated, this time using with Epoxies 40-3900 silver filled epoxy resin (Epoxies, Etc., Cranston, R.I.) in place of the conductive ink. In this experiment, the ratio of the nickel-coated diamond particles to the epoxy adhesive was on the order of 1 to 19 as the particles, as the weight of the particles only accounted for five percent of the weight of the mixture. First, the two components of the epoxy—catalyst and resin—were mixed at a ratio of one to one. Then 1 gram of the Amplex nickel-coated diamonds was mixed with 19 grams of the epoxy adhesive. The mixture was applied through a 50-micron thick stencil on both aluminum and copper substrates. The mixture was cured for 10 minutes at 110° C. Optical inspection, adhesion, and electrical conductivity results were identical with the results of the first and second experiments.

Experiment 4

The first experiment was again repeated, but in this instance, instead of mixing the nickel-coated diamond particles into the ink in a dish, the ink was applied independently to the metal panels through the stencil. The particles were then sprinkled over the “wet” ink. The spatula was used to gently press the particles into the ink. The recommended cure schedule for the ink was again followed. As before, optical inspection, adhesion, and electrical conductivity results were identical to the first experiment.

In summary, all the above formulations are electrically conductive; have a rough, sandpaper-like surface; and adhere well to copper, aluminum and stainless steel.

Although various embodiments of this invention have been described above with a certain degree of particularity, or with reference to one or more individual embodiments, those skilled in the art could make numerous alterations to the disclosed embodiments without departing from the spirit or scope of this invention. It is intended that all matter contained in the above description and shown in the accompanying drawings shall be interpreted as illustrative only of particular embodiments and not limiting. Changes in detail or structure may be made without departing from the basic elements of the invention as defined in the following claims.

What is claimed is:

1. A composition for creating an electrically conductive contact on an electrically conductive surface, the composition comprising:
a viscous compound capable of adhering to the electrically conductive surface,
wherein the viscous compound comprises a precursor to an electrically conductive solid formed upon cure of the viscous compound; and
a plurality of electrically conductive hard particles,
wherein at least a portion of the plurality of conductive hard particles form a rough, conductive, sandpaper-like surface to the electrically conductive solid, and
wherein the plurality of electrically conductive hard particles has a hardness at least as great as that of an opposing electrically conductive surface to be joined in electrical and mechanical connection to the electrically conductive surface.

2. The composition as described in claim 1, wherein the plurality of electrically conductive hard particles is a plurality of metal particles comprising at least one of the following: copper, aluminum, nickel, tin, bismuth, silver, gold, platinum, palladium, lithium, beryllium, boron, sodium, magnesium, potassium, calcium, gallium, germanium, rubidium, strontium, indium, antimony, cesium, and barium, and alloys and intermetallics of these metals.

3. The composition as described in claim 1, wherein the plurality of electrically conductive hard particles comprises a plurality of non-electrically-conductive particle cores surrounded by a metal layer.

4. The composition as described in claim 3, wherein the plurality of non-electrically-conductive particle cores comprises at least one of the following: diamond, garnet, ceramic, oxides, silicides, silicates, carbides, carbonates, borides, boron fibers, and nitrides.

5. The composition as described in claim 3, wherein the metal layer comprises at least one of the following: copper, aluminum, nickel, tin, bismuth, silver, gold, platinum, palladium, lithium, beryllium, boron, sodium, magnesium, potassium, calcium, gallium, germanium, rubidium, strontium, indium, antimony, cesium, and barium, and alloys and intermetallics of these metals.

6. The composition as described in claim 3, wherein the metal layer comprises a nickel layer and wherein the plurality of non-electrically-conductive particle cores comprises diamond.

7. The composition as described in claim 1, wherein the viscous compound comprises an electrically conductive ink.

8. The composition as described in claim 1, wherein the viscous compound comprises an electrically conductive paste.

9. The composition as described in claim 1, wherein the viscous compound comprises an electrically conductive adhesive.

10. The composition as described in claim 1, wherein the electrically conductive surface comprises a contact pad of an integrated circuit chip.

11. The composition as described in claim 1, wherein the electrically conductive surface comprises a plurality of discrete electrically conductive surfaces.

12. The composition as described in claim 11, wherein the plurality of discrete electrically conductive surfaces are electrically insulated from each other.

13. The composition as described in claim 11, wherein the plurality of discrete electrically conductive surfaces comprises an area array contact configuration of an integrated circuit chip.

14. The composition as described in claim 11, wherein the plurality of discrete electrically conductive surfaces comprises a plurality of contact surfaces of integrated circuit devices on a semiconductor wafer.

15. A method for creating an electrically conductive contact bump on an electrically conductive surface of an electrical component, the method comprising:
placing a stencil on the electrical component,
wherein the stencil comprises a pattern of an aperture through which the electrically conductive surface is exposed;
mixing a viscous compound with a plurality of electrically conductive hard particles,
wherein the viscous compound comprises a precursor to an electrically conductive solid formed upon cure of the viscous compound,
wherein the viscous compound is capable of adhering to the electrically conductive surface, and
wherein each of the plurality of electrically conductive hard particles has a hardness at least as great as that of an opposing electrically conductive surface to be joined in electrical and mechanical connection to the electrically conductive surface;
applying the viscous compound and electrically conductive hard particle mixture to the electrically conductive surface through the aperture in the stencil;
removing the stencil from the electrical component; and
curing the viscous compound and electrically conductive hard particle mixture applied to the electrically conductive surface to form the electrically conductive solid,
wherein at least a portion of the plurality of conductive hard particles form a rough, conductive, sandpaper-like surface to the electrically conductive solid.

16. A method for creating an electrically conductive contact bump on an electrically conductive surface of an electrical component, the method comprising:
placing a stencil on the electrical component,
wherein the stencil comprises a pattern of an aperture through which the electrically conductive surface is exposed;
applying a viscous compound to the electrically conductive surface through the aperture in the stencil,
wherein the viscous compound comprises a precursor to an electrically conductive solid formed upon cure of the viscous compound, and
wherein the viscous compound is capable of adhering to the electrically conductive surface;
removing the stencil from the electrical component;
depositing a plurality of electrically conductive hard particles over the viscous compound applied to the electrically conductive surface,
wherein each of the plurality of electrically conductive hard particles has a hardness at least as great as that of an opposing electrically conductive surface to be joined in electrical and mechanical connection to the electrically conductive surface; and
curing the viscous compound to form the electrically conductive solid,
wherein at least a portion of the plurality of conductive hard particles form a rough, conductive, sandpaper-like surface to the electrically conductive solid.

17. A method for creating an electrically conductive contact bump on an electrically conductive surface of an electrical component, the method comprising:
placing a screen on the electrical component
wherein the screen comprises a pattern of an exposed area and a non-exposed area,
wherein the exposed area is impervious to printable viscous compounds and particles,
wherein the non-exposed area comprises a grid defining apertures through which printable viscous compounds and particles of appropriate size may pass, and
wherein the non-exposed area is aligned with the electrically conductive surface;
mixing a viscous compound with a plurality of electrically conductive hard particles,
wherein the viscous compound comprises a precursor to an electrically conductive solid formed upon cure of the viscous compound,
wherein the viscous compound is capable of adhering to the electrically conductive surface,
wherein each of the plurality of electrically conductive hard particles has a hardness at least as great as that of an opposing electrically conductive surface to be joined in electrical and mechanical connection to the electrically conductive surface, and
wherein each of the plurality of electrically conductive hard particles is sized to pass through the grid apertures in the screen;
applying the viscous compound and electrically conductive hard particle mixture to the electrically conductive surface by pressing the mixture through the grid apertures in the non-exposed area of the screen;
removing the screen from the electrical component; and
curing the viscous compound and electrically conductive hard particle mixture applied to the electrically conductive surface to form the electrically conductive solid,
wherein at least a portion of the plurality of conductive hard particles form a rough, conductive, sandpaper-like surface to the electrically conductive solid.

18. A method for creating an electrically conductive contact bump on an electrically conductive surface of an electrical component, the method comprising:
placing a screen on the electrical component
wherein the screen comprises a pattern of an exposed area and a non-exposed area,
wherein the exposed area is impervious to printable viscous compounds,
wherein the non-exposed area comprises a grid defining apertures through which printable viscous compounds may pass, and
wherein the non-exposed area is aligned with the electrically conductive surface;
applying a viscous compound to the electrically conductive surface by pressing the viscous compound through the grid apertures in the non-exposed area of the screen,
wherein the viscous compound comprises a precursor to an electrically conductive solid formed upon cure of the viscous compound, and
wherein the viscous compound is capable of adhering to the electrically conductive surface;
removing the screen from the electrical component;
depositing a plurality of electrically conductive hard particles over the viscous compound applied to the electrically conductive surface,
wherein each of the plurality of electrically conductive hard particles has a hardness at least as great as that of an opposing electrically conductive surface to be joined in electrical and mechanical connection to the electrically conductive surface; and
curing the viscous compound to form the electrically conductive solid,
wherein at least a portion of the plurality of conductive hard particles form a rough, conductive, sandpaper-like surface to the electrically conductive solid.

19. The method as described in claim 15, 16, 17, or 18, wherein the plurality of electrically conductive hard particles is a plurality of metal particles comprising at least one of the following: copper, aluminum, nickel, tin, bismuth, silver, gold, platinum, palladium, lithium, beryllium, boron, sodium, magnesium, potassium, calcium, gallium, germanium, rubidium, strontium, indium, antimony, cesium, and barium, and alloys and intermetallics of these metals.

20. The method as described in claim 15, 16, 17, or 18, wherein the plurality of electrically conductive hard particles comprises a plurality of non-electrically-conductive particle cores surrounded by a metal layer.

21. The method as described in claim 20, wherein the plurality of non-electrically-conductive particle cores comprises of at least one of the following: diamond, garnet, ceramic, oxides, suicides, silicates, carbides, carbonates, borides, boron fibers, and nitrides.

22. The method as described in claim 20, wherein the metal layer comprises at least one of the following: copper, aluminum, nickel, tin, bismuth, silver, gold, platinum, palladium, lithium, beryllium, boron, sodium, magnesium, potassium, calcium, gallium, germanium, rubidium, strontium, indium, antimony, cesium, and barium, and alloys and intermetallics of these metals.

23. The method as described in claim 20, wherein the metal layer comprises a nickel layer and wherein the plurality of non-electrically-conductive particle cores comprises diamond.

24. The method as described in claim 15, 16, 17, or 18, wherein the viscous compound comprises an electrically conductive ink.

25. The method as described in claim 15, 16, 17, or 18, wherein the viscous compound comprises an electrically conductive paste.

26. The method as described in claim 15, 16, 17, or 18, wherein the viscous compound comprises an electrically conductive adhesive.

27. The method as described in claim 15, 16, 17, or 18, wherein the electrically conductive surface comprises a contact pad of an integrated circuit chip.

28. The method as described in claim 15, 16, 17, or 18, wherein the electrically conductive surface comprises a plurality of discrete electrically conductive surfaces.

29. The method as described in claim 28, wherein the plurality of discrete electrically conductive surfaces are electrically insulated from each other.

30. The method as described in claim 28, wherein the plurality of discrete electrically conductive surfaces comprises an area array contact configuration of an integrated circuit chip.

31. The method as described in claim 28, wherein the plurality of discrete electrically conductive surfaces comprises a plurality of contact surfaces of integrated circuit devices on a semiconductor wafer.
